(19) United States
(12) Patent Application Publication
(10) Pub. No.: US 2010/0149099 A1
(43) Pub. Date: Jun. 17, 2010

(54) MOTION SENSITIVE MECHANICAL KEYBOARD

(76) Inventor: John Greer ELIAS, Townsend, DE (US)

Correspondence Address: APPLE C/O MORRISON AND FOERSTER ,LLP;LOS ANGELES, 555 WEST FIFTH STREET SUITE 3500, LOS ANGELES, CA, 90013-1024, US

(21) Appl. No.: 12/334,320

(22) Filed: Dec. 12, 2008

(51) Int. Cl. G06F 3/02; H03M 11/00

(52) U.S. Cl. 345/168; 341/26

(57) ABSTRACT

A motion sensitive mechanical keyboard configured to enable a standard look and feel mechanical keyboard to sense hand/finger motion over the surface of the keys. Command and cursor input (e.g., pointing and gestures) can be received from the user on the motion sensitive mechanical keyboard without requiring the user to move the user's hand off the keyboard. Hand/finger motion can be detected by optical sensors via an in-keyboard-plane slot camera system. The motion sensitive mechanical keyboard can operate in two or more modes—e.g., a typing mode and a mouse mode—and operating the keyboard in mouse mode or switching between the modes can be facilitated by holding (depressing and holding) or tapping (depressing and releasing) arbitrary combinations of keys.

### FIELD OF THE INVENTION

This invention generally relates to input devices for computing systems, and more particularly, to improving the user interface experience associated with key-based input devices.

### BACKGROUND OF THE INVENTION

A computer keyboard is a peripheral modeled after the typewriter keyboard. Keyboards are used to provide textual input into the computer and to control the operation of the computer. Physically, computer keyboards are generally an arrangement of rectangular or near-rectangular buttons or “keys,” which typically have engraved or printed characters. In most cases, each depressing of a key corresponds to a single character. However, some characters require that a user depress and hold several keys concurrently or in sequence. Depressing and holding several keys concurrently or in sequence can also result in a command being issued that affects the operation of the computer, or the keyboard itself.

There are several types of keyboards, usually differentiated by the switch technology employed in their operation. The choice of switch technology can affect the keys' response (i.e., the positive feedback that a key has been depressed) and travel (i.e., the distance needed to push the key to enter a character reliably). One of the most common keyboard types is a “dome-switch” keyboard which works as follows. When a key is depressed, the key pushes down on a rubber dome sitting beneath the key. The rubber dome collapses, which gives tactile feedback to the user depressing the key, and causes a conductive contact on the underside of the dome to touch a pair of conductive lines on a Printed Circuit Board (PCB) below the dome, thereby closing the switch. A chip in the keyboard emits a scanning signal along the pairs of lines on the PCB to all the keys. When the signal in one pair of the lines changes due to the contact, the chip generates a code corresponding to the key connected to that pair of lines. This code is sent to the computer either through a keyboard cable or over a wireless connection, where it is received and decoded into the appropriate key. The computer then decides what to do on the basis of the key depressed, such as display a character on the screen or perform some action. Other types of keyboards operate in a similar manner, with the main differences being how the individual key switches work. Some examples of other keyboards include capacitive-switch keyboards, mechanical-switch keyboards, Hall-effect keyboards, membrane keyboards, roll-up keyboards, and so on.

Conventional mechanical keyboards are generally accepted as the preferred means to provide textual input. These keyboards have mechanical keys that are configured to move independently of one another and comply with standards for key spacing and actuation force. These keyboards are also arranged in the so-called QWERTY layout. Over the last forty years there have been numerous attempts made to introduce an alternative to the standard keyboard. The changes include, but are not limited to, non-QWERTY layouts, concave and convex surfaces, capacitive keys, split designs, membrane keys, etc. However, although such alternative keyboards may provide improved usability or ergonomics, they have failed to replace or duplicate the commercial success of the conventional mechanical keyboard.

### SUMMARY OF THE INVENTION

A motion sensitive mechanical keyboard is disclosed. The motion sensitive mechanical keyboard improves the user interface experience associated with key-based input devices.

The motion sensitive mechanical keyboard enables a standard look and feel mechanical keyboard to sense hand/finger motion over the surface of the keys such that command and cursor input (e.g., pointing and gestures) can be received from the user without requiring the user to move the user's hand off the keyboard.

Hand/finger motion can be detected by optical sensors via an in-keyboard-plane slot camera system. The motion sensitive mechanical keyboard can operate in two or more modes—e.g., a typing mode and a mouse mode—and operating the keyboard in mouse mode or switching between the modes can be facilitated by holding (depressing and holding) or tapping (depressing and releasing) arbitrary combinations of keys.

### BRIEF DESCRIPTION OF THE DRAWINGS

FIG. 1 illustrates an exemplary motion sensitive mechanical keyboard according to one embodiment of the invention.

FIG. 2 illustrates an exemplary process for providing cursor input with a motion sensitive mechanical keyboard according to one embodiment of the invention.

FIGS. 3A-3C illustrate exemplary hand controls for operating a motion sensitive mechanical keyboard according to embodiments of the invention.

FIG. 4 illustrates an exemplary in-keyboard plane slot camera configuration for surface monitoring a motion sensitive mechanical keyboard according to an embodiment of the invention.

FIG. 5 illustrates an exemplary computing system including an input device according to embodiments of the invention.

FIGS. 6A and 6B illustrate exemplary personal computers having a motion sensitive mechanical keyboard according to embodiments of the invention.

### DETAILED DESCRIPTION OF THE PREFERRED EMBODIMENTS

In the following description of preferred embodiments, reference is made to the accompanying drawings where it is shown by way of illustration specific embodiments in which the invention can be practiced. It is to be understood that other embodiments can be used and structural changes can be made without departing from the scope of the embodiments of this invention.

Embodiments of the invention relate to enabling a standard look and feel mechanical keyboard to sense hand/finger motion over the surface of the keys such that command and cursor input (e.g., pointing and gestures) can be received from the user without requiring the user to move the user's hand off the keyboard. Hand/finger motion can be detected by optical sensors via an in-keyboard-plane slot camera system. The motion sensitive mechanical keyboard can operate in two or more modes—e.g., a typing mode and a mouse mode—and operating the keyboard in mouse mode or switching between the modes can be facilitated by holding (depressing and holding) or tapping (depressing and releasing) arbitrary combinations of keys.

Although some embodiments of this invention may be described and illustrated herein in terms of an input device associated with a standalone computer keyboard, it should be understood that embodiments of this invention are not so limited, but are generally applicable to motion sensitive mechanical keys associated with any device or structure, such as automated teller machines (ATMs), kiosks/information booths, key pads, automated check-in terminals at airports, automated check-out machines at retail stores, etc.

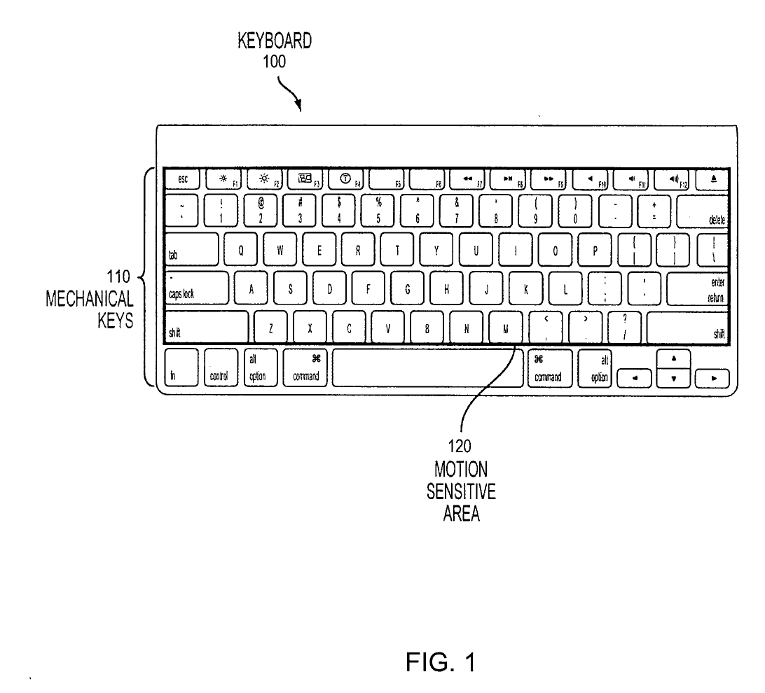

FIG. 1 illustrates motion sensitive mechanical keyboard 100 having mechanical keys 110 and motion sensitive area 120 spanning all of keys 110 except for the bottom-most row. In other embodiments, motion sensitive area 120 can span all keys 110 or any region of keys 110 on keyboard 100. To maximize the likelihood of acceptance with the general population, keyboard 100 has the look and feel of a conventional keyboard. By integrating hand/finger motion tracking input capability into keyboard 100 without altering its overall appearance or, more importantly, the familiar way in which it is used for typing, most of the benefits of a gesture-based input capability can be realized without having any negative impact on the user's text entry experience. Cursor input functions, such as point, click, scroll, drag, select and zoom for example, can be enabled with keyboard 100 such that the user can invoke any one of these functions without moving the user's hands off keyboard 100. These functions, and more, can be driven by hand/finger motion while the fingers are sliding over and touching keys 110 of keyboard 100.

Keyboard 100 can operate in two or more distinct modes in one embodiment: e.g., a typing mode and a mouse mode. While in typing mode, the normal movement of objects such as hands and fingers can be ignored by the motion sensing circuitry. This ensures that nothing unexpected happens like the cursor moving, the page scrolling, or the screen zooming as the user moves the user's fingers across the keys while typing. In typing mode, keyboard 100 operates as normal, accepting single key taps as text or number inputs, for example. Modifier key, hot key, and function key input also operate as normal in typing mode. In other words, keyboard 100 functions and feels just like one would expect a conventional mechanical keyboard to function and feel when in typing mode.

In mouse mode, typing, for the most part, can be disabled. In mouse mode, motion sensing circuitry associated with keyboard 100 can track the movement of the user's hands/fingers in order to provide cursor input, such as moving the cursor, scrolling, dragging or zooming, for example, with a one-to-one correlation between hand/finger motion and the desired action of moving something on the screen. Either hand can be used to guide the motion of the on-screen action. As a result, left-handed users can provide cursor input just as easily as right-handed users can.

In typing mode, the keys can be tapped one at a time (except when modifier keys are used, for example) and the hand/finger motion accompanying the typing execution can be ignored by the motion sensing circuitry.

Separating the function of keyboard 100 into two or more distinct modes that the user deliberately invokes has the advantage of eliminating the chance that random or postural changes in hand/finger position can be misinterpreted as a cursor input (e.g., point, scroll, drag, zoom). In this manner, keyboard 100 does not need to determine when the user intends to issue commands to control screen activities (e.g., scrolling) because the user informs keyboard 100 of the user's intent by switching modes. Mode switching can be implemented in various ways. In some embodiments, mode switching can be implemented in ways that do not require the user to look down at keyboard 100, thereby improving the user experience. In one embodiment, a dedicated “mouse” key can be provided such that mouse mode is entered for the duration that the mouse key is held down. In another embodiment, the dedicated mouse key can comprise a “sticky” key, such that a tap of the key switches between modes. In a further embodiment, the modes can be switched when the user concurrently taps an arbitrary combination of the keys. For example, in one embodiment, the arbitrary combination of the keys can include any four of keys 110. In another embodiment, the arbitrary combination of the keys can be restricted to adjacent keys in order to effect the mode switch.

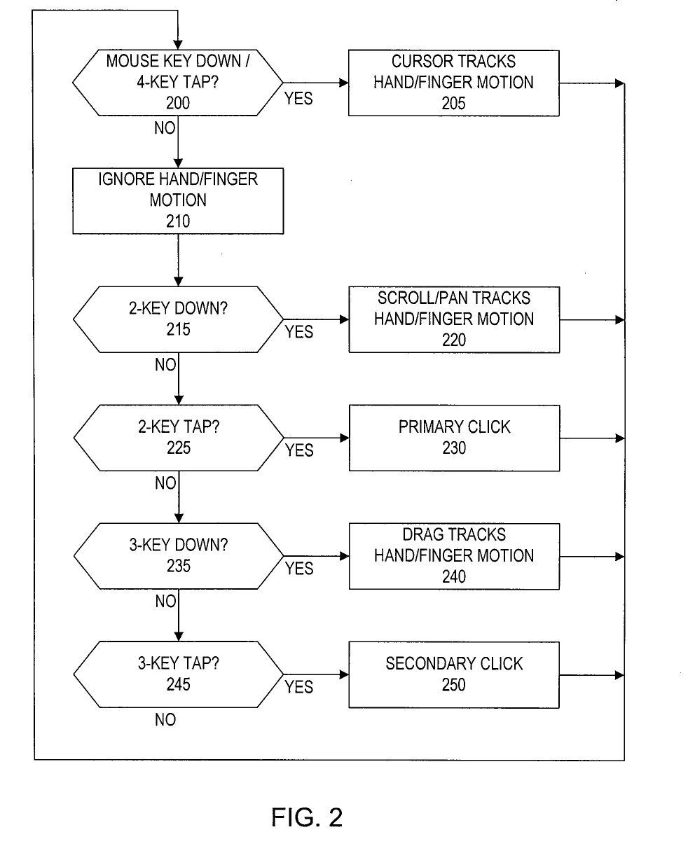

FIG. 2 illustrates a process for switching between typing and mouse operations using keyboard 100. In mouse mode in the illustrated embodiment, the hand that is not being used for pointing or gesturing can hold down a number of adjacent keys (e.g., 2, 3, or 4) while the other hand/fingers move about the keyboard surface and are tracked by the motion sensing circuitry. For example, while a dedicated mouse key is held down or if a 4-key tap occurs (block 200), keyboard 100 can enter mouse mode such that motion sensing circuitry tracks hand/finger motion (block 205). If not, keyboard 100 can remain in typing mode and hand/finger motion can be ignored (block 210). While two keys are held down (block 215), motion sensing circuitry can track hand/finger motion to effect a scroll (for detected horizontal motion) and pan (for detected vertical motion) (block 220). Keyboard 100 can also interpret a two-key tap (block 225) as a primary click (similar to a left click on a conventional mouse) (block 230). While three keys are held down (block 235), the motion sensing circuitry can track hand/finger motion to effect a drag operation (similar to a click-hold and drag operation by a conventional mouse) (block 240). Keyboard 100 can also interpret a three-key tap (block 245) as a secondary click (similar to a right click on a conventional mouse) (block 250).

It is noted that any suitable number of keys may be utilized in the key tap and hold down operations described in the embodiments illustrated in FIG. 2. The keys may be dedicated (i.e., the same keys can be required to effect the designated operation) or arbitrary (i.e., any of the specified number of keys on keyboard 100—or in any region of keyboard 100—can effect the designated operation). In another embodiment, keyboard 100 can allow non-adjacent keys to effect the described key tap and hold down operations. It is also noted that a user need not explicitly enter mouse mode prior to effecting the operations described in blocks 220, 230, 240 and 250.

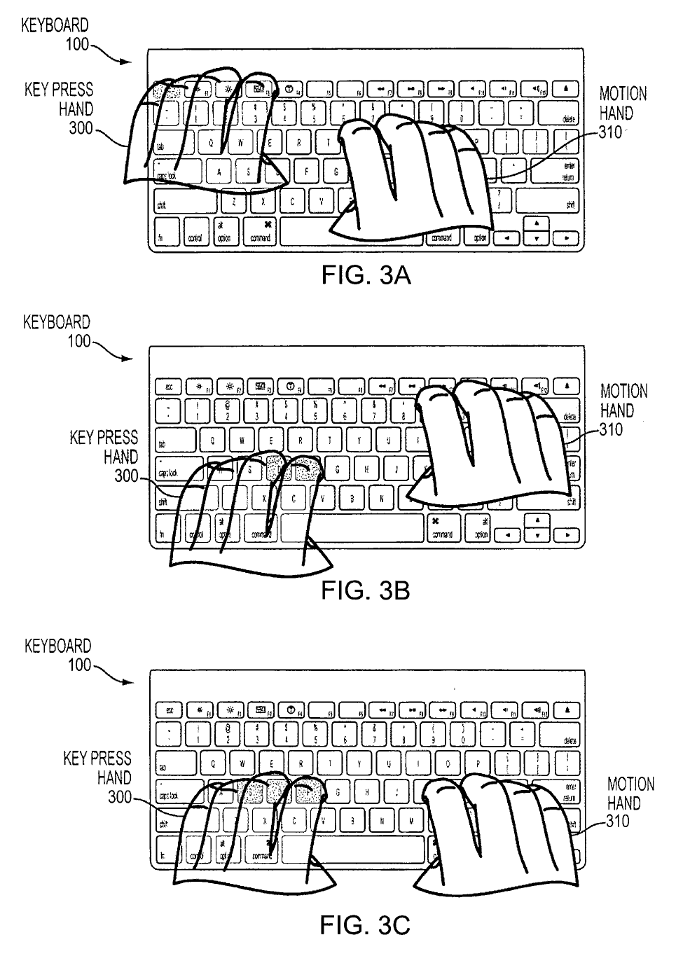

FIGS. 3A-3C illustrate examples of pointing (FIG. 3A), scrolling/panning (FIG. 3B), and dragging (FIG. 3C) according the embodiments of the present invention. In FIG. 3A, key press hand 300 can hold down a mouse-key while the hand/finger movement of motion hand 310 can be tracked by the motion sensing circuitry, which can cause the cursor to follow the hand/finger movement. In FIG. 3B, key press hand 300 can hold down two adjacent keys while the hand/finger movement of motion hand 310 can be tracked by the motion sensing circuitry. Up and down movement can control scroll while left and right movement can control pan. In FIG. 3C, key press hand 300 hand can hold down three adjacent keys while the hand/finger movement of motion hand 310 can be tracked by the motion sensing circuitry. The hand/finger movement can control the drag function.

As described above in connection with selection operations, tapping two adjacent keys can produce a primary mouse click, while tapping three adjacent keys can produce a secondary mouse click. To illustrate how this works, presume the user enters mouse mode by holding down the mouse-key with the user's left pinky finger. The cursor can then follow the movement of the user's right hand and fingers. When the user has moved the cursor to the intended target and is ready to click on it, the user can release the mouse key. This can stop the motion sensing circuitry from tracking the user's hand/finger motion. The user can tap two adjacent keys to enter a primary mouse click. Either hand can be used to tap the two keys, and, if desired, the user does not have to release the mouse key to invoke a mouse click. Not releasing the mouse key may introduce some risk that the cursor could move before the two keys are tapped, but some users may be able to do so without a problem. The whole operation of pointing, releasing the mouse key, and tapping two adjacent keys is smooth, fast, and easy to coordinate.

Other functions can be supported in addition to the commonly used cursor input functions of point, scroll, drag, and zoom. For example, hand rotation and hand expansion/contraction gestures can be used for zooming and/or opening and closing files; hand swipes and slides can be used to accelerate operations like text cursor positioning; and two-hand motion monitoring can be used by employing a sticky mouse-key which enables both hands to provide cursor input motion in mouse mode.

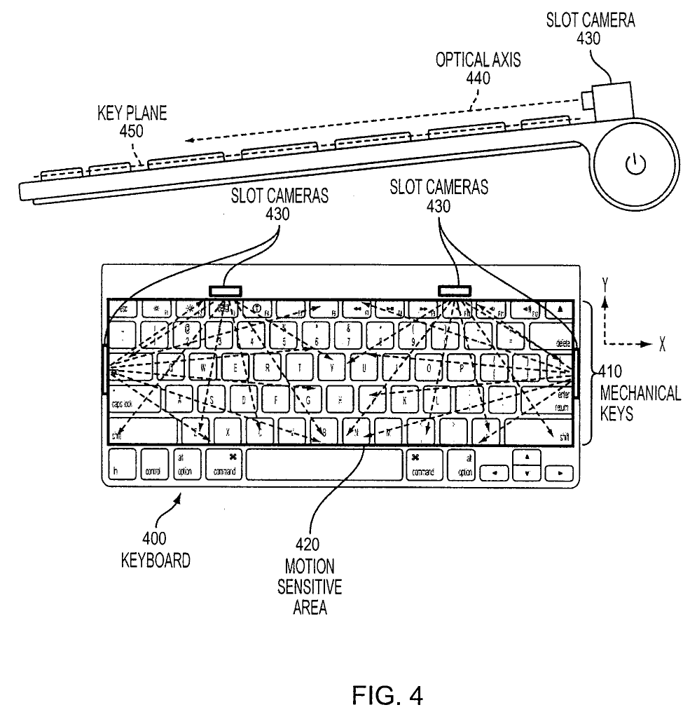

Motion sensing associated with keyboard 100 can be implemented with optical sensing using an in-keyboard-plane slot camera system. An exemplary in-keyboard-plane slot camera system is illustrated in FIG. 4. In this embodiment, four slot cameras 430 can be used to track the XYZ motion of the user's hands/fingers. Slot camera 430 can be, for example, a video camera that has a standard aspect ratio or a special high aspect ratio camera that reduces the number of pixel rows such that the field of view is reduced in the Z direction (i.e., perpendicular to the surface of key plane 450). In other words, the imaging array can be organized such that most of slot camera 430's pixels are dedicated to imaging in key plane 450 (i.e., XY) and fewer pixels are dedicated to imaging perpendicular to the plane (i.e., Z). The optical sensors of slot cameras 430 can be oriented toward keys 410 such that their optical axes are parallel to key plane 450. Suitable image analysis techniques, such as techniques employing edge detection algorithms for example, can be utilized to detect the motion of the user's hands/fingers. Such detection can be based on a pixel row or rows parallel to key plane 450, for example.

As illustrated in FIG. 4, slot cameras 430 can be arranged two on the left and two on the right to capture the XYZ motion of the respective hands/fingers. The arrows in FIG. 4 attempt to illustrate the field of view of cameras 410. An advantage of this slotted camera system is that the cameras are always in the correct position, and can be of low profile (in an embodiment as illustrated in FIG. 4 in which cameras 410 are disposed on the surface of keyboard 100 and oriented toward keys 410) and even hidden in the keyboard enclosure (in an embodiment in which mirrors embedded in projections arising from a surface of keyboard 100 orient cameras 430 toward keys 410). Additionally, Z data can be provided which can be used for cursor input operations that discriminate between hands/fingers resting on keys 410 and the hands/fingers being lifted off keys 410.

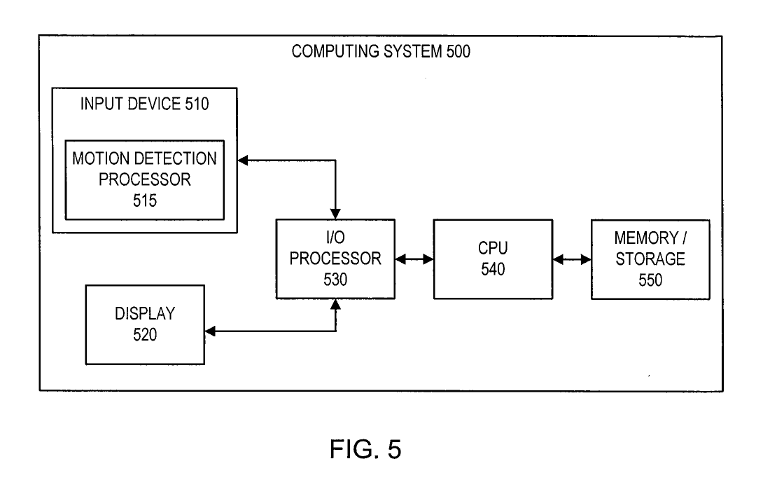

FIG. 5 illustrates exemplary computing system 500 that can implement embodiments of the invention as described above. Computing system 500 can include input device 510, display 520, I/O processor 530, central processing unit (CPU) 540 and memory/storage 550. Input device 510 can correspond to a motion sensitive mechanical keyboard such as keyboard 100 described above, and can include motion detection processor 515 to process the video data stream(s) to track the movement of hands and fingers engaging input device 510. Programming for processing the input captured by input device 510 may be stored in memory/storage 550 of computing system 500, which may include solid state memory (RAM, ROM, etc.), hard drive memory, and/or other suitable memory or storage. CPU 540 may retrieve and execute the programming to process the input received through input device 510. Through the programming, CPU 540 can receive outputs from input device 510 and perform actions based on the outputs that can include, but are not limited to, moving an object such as a cursor or pointer, scrolling or panning, adjusting control settings, opening a file or document, viewing a menu, making a selection, executing instructions, operating a peripheral device coupled to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. CPU 540 can also perform additional functions that may not be related to input device processing, and can be coupled to memory/storage 550 and display 520, which may include a liquid crystal display (LCD) for example, for providing a user interface (UI) to a user of the device.

Note that one or more of the functions described above can be performed by firmware stored in a memory (not shown) associated with motion detection processor 515 and executed by motion detection processor 515, stored in a memory (not shown) associated with I/O processor 530 and executed by I/O processor 530, or stored in memory/storage 550 and executed by CPU 540. The firmware can also be stored and/or transported within any computer-readable storage medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable storage medium” can be any medium that can contain or store a program for use by or in connection with the instruction execution system, apparatus, or device. The computer readable storage medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport readable medium can include, but is not limited to, an electronic, magnetic, optical, electromagnetic or infrared wired or wireless propagation medium.

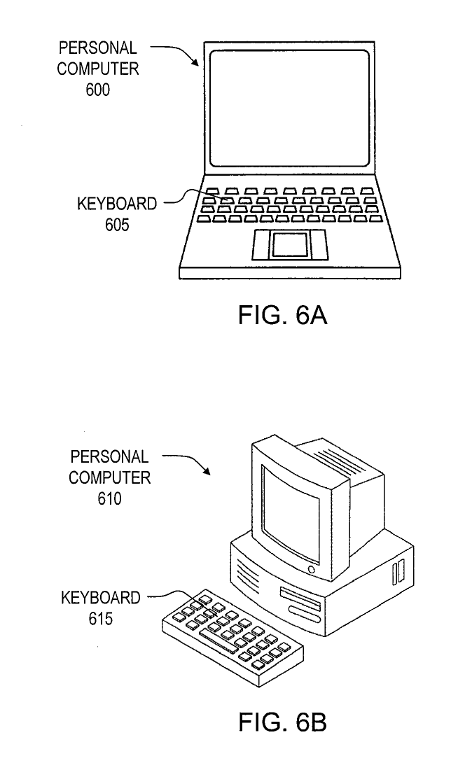

Computing system 500 can be any of a variety of types employing a motion sensitive mechanical keyboard, such as those illustrated in FIGS. 6A-6B, for example. FIGS. 6A and 6B illustrate exemplary personal computers 600 (in a laptop configuration) and 610 (in a desktop system configuration) that can include motion sensitive mechanical keyboards 605 and 615, respectively, according to embodiments of the invention. The personal computers of FIGS. 6A-6B can achieve an improved user interface by utilizing a motion sensitive mechanical keyboard according to embodiments of the invention.

Although embodiments of this invention have been fully described with reference to the accompanying drawings, it is to be noted that various changes and modifications will become apparent to those skilled in the art. Such changes and modifications are to be understood as being included within the scope of embodiments of this invention as defined by the appended claims.

What is claimed is:

1. An input device comprising:
multiple mechanical keys aligned in a plane; and
multiple optical sensors oriented toward the keys and having optical axes parallel to the plane.

2. The input device of claim 1, wherein the optical sensors are configured to track motion of one or more objects in contact with or in proximity to the keys.

3. The input device of claim 2, wherein the optical sensors are configured to track the motion of the one or more objects along the plane.

4. The input device of claim 2, wherein the optical sensors are configured to track the motion of the one or more objects orthogonal to the plane.

5. The input device of claim 1, wherein a first of the optical sensors has an optical axis in a first direction parallel to the plane, and a second of the optical sensors has an optical axis in a second direction parallel to the plane and orthogonal to the first direction.

6. The input device of claim 1, wherein each of the multiple optical sensors comprises a camera.

7. The input device of claim 1, wherein the input device is a keyboard.

8. The input device of claim 7, wherein the optical sensors are embedded within the keyboard, and mirrors orient the optical sensors toward the keys.

9. The input device of claim 7, wherein the optical sensors are integrated into projections arising from the keyboard.

10. An input device comprising:
multiple mechanical keys;
first sensors configured to detect depression of the keys; and
second sensors configured to track motion across the keys while an arbitrary combination of the keys is concurrently depressed.

11. The input device of claim 10, wherein the motion tracked by the second sensors implements a scroll or pan operation in a user interface associated with the input device.

12. The input device of claim 10, wherein the motion tracked by the second sensors implements a drag operation in a user interface associated with the input device.

13. The input device of claim 10, wherein the arbitrary combination of the keys comprises adjacent keys.

14. The method of claim 11, wherein the arbitrary combination of the keys comprises two of the keys.

15. The method of claim 12, wherein the arbitrary combination of the keys comprises three of the keys.

16. A method, comprising:
providing a first input mode associated with multiple mechanical keys in which detection of depression of the keys to provide textual input is enabled and tracking of motion across the keys to provide cursor input is disabled;
providing a second input mode associated with the keys in which tracking of motion across the keys to provide cursor input is enabled; and
switching between the first input mode and the second input mode when an arbitrary combination of the keys is concurrently depressed and released.

17. The method of claim 10, wherein the arbitrary combination of the keys comprises four of the keys.

18. The method of claim 10, wherein the arbitrary combination of the keys comprises adjacent keys.

19. The method of claim 10, wherein detection of depression of the keys to provide textual input is enabled in the second input mode.

20. The method of claim 10, wherein detection of depression of the keys to provide textual input is disabled in the second input mode.

21. A personal computer comprising:
multiple mechanical keys aligned in a plane; and
multiple optical sensors oriented toward the keys and having optical axes parallel to the plane.
